(19) United States
(12) Patent Application Publication
(10) Pub. No.: US 2018/0220551 A1
(43) Pub. Date: Aug. 2, 2018

(54) TELECOMMUNICATIONS EQUIPMENT ENCLOSURES HAVING HEAT EXCHANGERS

(71) Applicant: VERTIV ENERGY SYSTEMS, INC., Lombard, IL (US)

(72) Inventor: Jin Harrison Elkins, LaGrange, GA (US)

(21) Appl. No.: 15/881,313

(22) Filed: Jan. 26, 2018

Related U.S. Application Data
(60) Provisional application No. 62/451,497, filed on Jan. 27, 2017.

(51) Int. Cl. H05K 7/20

(52) U.S. Cl. CPC H05K 7/20172; H05K 7/20145

(57) ABSTRACT

A telecommunications equipment enclosure includes a plurality of walls defining a chamber for housing a heat generating component, an air heat exchanger, and at least two fans. The air heat exchanger defines a first airflow path through the air heat exchanger and internal to the chamber, and a second airflow path through the air heat exchanger and external to the chamber. The at least two fans are positioned in a series airflow arrangement in the first airflow path or the second airflow path. The at least two fans are configured to move air through the first airflow path or the second airflow path to remove heat from the chamber. Other examples telecommunications equipment enclosures are also disclose.

### CROSS-REFERENCE TO RELATED APPLICATIONS

This application claims the benefit and priority of U.S. Provisional Application No. 62/451,497 filed Jan. 27, 2017. The entire disclosure of the above application is incorporated herein by reference.

### FIELD

The present disclosure relates to telecommunications equipment enclosures having heat exchangers.

### BACKGROUND

This section provides background information related to the present disclosure which is not necessarily prior art.

Telecommunications equipment enclosures include telecommunications components. Commonly, these components include heat generating components. In some cases, the telecommunications equipment enclosures may include a heat exchanger to remove heat generated by the telecommunications components. Sometimes, the enclosures includes one or more fans to force air through and/or across the heat exchanger's core and assist in removing heat from the enclosures.

### SUMMARY

This section provides a general summary of the disclosure, and is not a comprehensive disclosure of its full scope or all of its features.

According to one aspect of the present disclosure, a telecommunications equipment enclosure includes a plurality of walls and an air heat exchanger. The plurality of walls define a chamber for housing a heat generating component. The air heat exchanger defines a first airflow path through the air heat exchanger and internal to the chamber, and a second airflow path through the air heat exchanger and external to the chamber. The telecommunications equipment enclosure also includes at least two fans positioned in a series airflow arrangement in the first airflow path for moving air through the first airflow path and removing heat from the chamber, and at least two fans positioned in a series airflow arrangement in the second airflow path for moving air through the second airflow path and removing heat from the chamber.

According to another aspect of the present disclosure, a telecommunications equipment enclosure includes a plurality of walls defining a chamber for housing a heat generating component, an air heat exchanger, and a first fan. The air heat exchanger defines a first airflow path through the air heat exchanger and internal to the chamber, and a second airflow path through the air heat exchanger and external to the chamber. The first fan is positioned in the first airflow path or the second airflow path for generating a required airflow at a particular speed and a particular noise level. The improvement includes a second fan positioned in a series airflow arrangement with the first fan for generating the required airflow. The series airflow arrangement allows each of the first fan and the second fan to operate at a lower speed than said particular speed and at a combined noise level lower than said particular noise level.

According to yet another aspect of the present disclosure, a telecommunications equipment enclosure includes a plurality of walls defining a chamber for housing a heat generating component, an air heat exchanger, and at least two fans. The air heat exchanger defines a first airflow path through the air heat exchanger and internal to the chamber, and a second airflow path through the air heat exchanger and external to the chamber. The at least two fans are positioned in a series airflow arrangement in the first airflow path or the second airflow path. The at least two fans are configured to move air through the first airflow path or the second airflow path to remove heat from the chamber.

Further aspects and areas of applicability will become apparent from the description provided herein. It should be understood that various aspects of this disclosure may be implemented individually or in combination with one or more other aspects. It should also be understood that the description and specific examples herein are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a block diagram of a telecommunications equipment enclosure including a chamber, an air heat exchanger, and two fans positioned in a series airflow arrangement to move air through an airflow path external to the chamber, according to one example embodiment of the present disclosure.

FIG. 2 is a block diagram of the heat exchanger and fans of FIG. 1.

FIG. 3 is a block diagram of a telecommunications equipment enclosure including a chamber, an air heat exchanger, and two fans positioned in a series airflow arrangement to move air through an airflow path internal to the chamber, according to another example embodiment.

FIG. 4 is a block diagram of a telecommunications equipment enclosure including an air heat exchanger and two sets of fans positioned in a series airflow arrangement according to yet another example embodiment.

FIG. 5A is a side view of a telecommunications equipment enclosure including a chamber, an air heat exchanger, and two sets of fans positioned in a series airflow arrangement, one of which moves air through an airflow path external to the chamber, according to another example embodiment.

FIG. 5B is a side view of the telecommunications equipment enclosure of FIG. 5A, but in which the other set of fans moves air through another airflow path internal to the chamber, according to yet another example embodiment.

FIG. 6 is an isometric view of a set of heat exchanger plates according to another example embodiment.

FIG. 7 is a side view of a telecommunications equipment enclosure including an air heat exchanger, and two fans positioned in a series airflow arrangement and adjacent the heat exchanger's exhaust port, according to yet another example embodiment.

FIG. 8 is a side view of a telecommunications equipment enclosure including an air heat exchanger, and two fans positioned in a series airflow arrangement and adjacent the heat exchanger's intake port, according to another example embodiment.

FIG. 9A is a block diagram of a heat exchanger, two fans adjacent the heat exchanger's intake port, and one fan adjacent the heat exchanger's exhaust port, in which the fans are positioned in a series airflow arrangement according to yet another example embodiment.

FIG. 9B is a block diagram of a heat exchanger, one fan adjacent the heat exchanger's intake port, and two fans adjacent the heat exchanger's exhaust port, in which the fans are positioned in a series airflow arrangement according to another example embodiment.

FIG. 9C is a block diagram of a heat exchanger and four fans, in which two of the fans are positioned in a series airflow arrangement and the other two fans are positioned in another series airflow arrangement, according to yet another example embodiment.

FIG. 10 is a graph plotting noise generated for a conventional fan configuration having two fans in a parallel arrangement and the series fan arrangement shown in FIG. 9A, according to another example embodiment.

FIG. 11 is a graph plotting noise generated for the series fan arrangement shown in FIG. 9C, according to yet another example embodiment.

Corresponding reference numerals may indicate corresponding parts and/or features throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

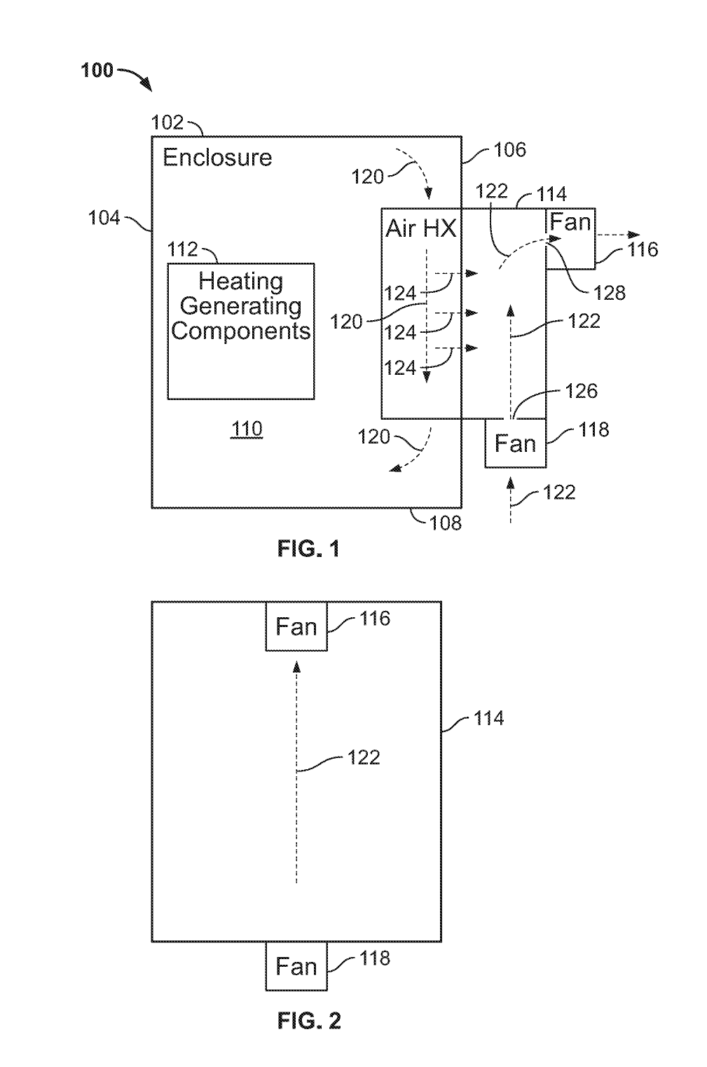

A telecommunications equipment enclosure according to one example embodiment of the present disclosure is illustrated in FIG. 1, and indicated generally by reference number 100. As shown in FIG. 1, the telecommunications equipment enclosure 100 includes walls defining a chamber 110 for housing one or more heat generating components 112, an air heat exchanger 114, and at least two fans 116, 118. The air heat exchanger 114 defines one airflow path (indicated by arrows 120) through the air heat exchanger 114 and internal to the chamber 110, and another airflow path (indicated by arrows 122) through the air heat exchanger 114 and external to the chamber 110. As shown, the fans 116, 118 are positioned in a series airflow arrangement in the airflow path 122. The fans 116, 118 are configured to move air through the airflow path 122 to remove heat from the chamber 110.

By employing the series arranged fans 116, 118 shown in FIG. 1 (and/or another set of series arranged fans as disclosed herein), the speed of the fans may be decreased and therefore the noise of the fans may be reduced as compared to conventional enclosures employing one or more fans. For example, enclosures increasingly include components generating large amounts of heat. To remove this large amount of heat, additional thermally conductive plates (sometimes referred to as fins) may be added to the enclosure's heat exchanger to provide more surface area for transferring heat. As a result of the increased number of plates, space between the plates is reduced thereby restricting the amount of airflow capable of passing through the heat exchanger's core. As such, a higher amount of pressure (sometimes referred to as static pressure) is required to force air through the heat exchangers plates. In some cases, the speed (e.g., revolutions per minute (RPM)) of one or more fans associated with a heat exchanger may be increased to a particular value to generate the desired static pressure and create a particular airflow through the heat exchanger. However, the inventor of the instant application recognized that the increased fan speed causes the noise level to rise to an unsatisfactory level even though these fans may create the desired airflow.

Instead of increasing fan speed, the inventor recognized that by positioning at least two fans associated with a heat exchanger in a series arrangement, the static pressure capability of the fans (in combination) increases as compared to conventional arrangements when the series arranged fans and the conventional fans are operated at substantially the same speed. In some cases, the static pressure capability of two fans positioned in a series airflow arrangement may be doubled compared to a single fan arrangement. For example, because the airflow through the heat exchanger core is restricted (e.g., due to the increased number of fins as explained above), the series arranged fans cause a pressure drop to increase between the heat exchanger's intake port and exhaust port. This increased pressure drop allows the speed of each fan to reduce while still creating the desired airflow through the heat exchanger. As a result of the reduced fan speed, the noise generated by the fans is maintained at an acceptable level while creating the desired airflow through the heat exchanger and removing the desired amount of heat from the enclosure. Thus, the series arranged fans are able to operate at lower speeds and at a combined noise level lower than conventional heat exchangers.

As explained above, the telecommunications equipment enclosure 100 includes various walls. Specifically, and as shown in FIG. 1, the enclosure 100 includes a top wall (e.g., the enclosure's ceiling) 102, side walls including the side walls 104, 106, and a bottom wall (e.g., the enclosure's floor) 108. These walls define the chamber 110, and one or more other chambers (e.g., a battery chamber, etc.) in the enclosure 100.

The heat exchanger 114 may include one or more thermally conductive plates to isolate the airflow paths 120, 122 from each other. For example, and as shown in FIG. 1, a portion of the enclosure's wall 106 may function as a heat exchanger plate isolating the internal airflow path 120 from the external airflow path 122. This ensures ambient air outside the enclosure 100 is not mixed with air (e.g., clean air) flowing inside the enclosure 100. Specifically, air in the airflow path 122 that flows through the air heat exchanger 114 and external to the chamber 110 is not mixed with air in the airflow path 120 that flows through the air heat exchanger 114 and internal to the chamber 110.

Additionally, and as explained above, the thermally conductive plates may be used to assist in removing heat from of the chamber 110 (and therefore the enclosure 100). For example, the enclosure's wall 106 may transfer heat from the internal airflow path 120 to the external airflow path 122, as further explained below. For instance, heat generated by the heat generating components 112 (and/or other heat inside the enclosure 100) may be carried to the heat exchanger 114 via air flowing in the airflow path 120. This heat is then passed through the thermally conductive plates (e.g., the enclosure's wall 106, etc.) in the heat exchanger 114 (e.g., as shown by arrows 124), and moved into air flowing in the airflow path 122. The air in the airflow path 122 moves the heat out of the heat exchanger 114 and the enclosure 100.

As shown in FIGS. 1 and 2, the fans 116, 118 are positioned in a series airflow arrangement. For example, the airflow generated by the fan 118 passes through the fan 116 in a push-pull arrangement. In other words, the fan 118 pulls air into the heat exchanger 114 and pushes it towards the fan 116, and the fan 116 pulls air out of the heat exchanger 114 and pushes it to an area external the heat exchanger 114 to create the airflow path 122. In other embodiments, the airflow path 122 may be reversed if desired.

As shown in FIG. 1, the heat exchanger 114 includes at least two ports 126, 128 for allowing ambient air to move into and/or out of the heat exchanger 114. In some examples, the ports 126, 128 may be considered a portion of the airflow path 122. For example, the port 126 may be considered an intake port to allow ambient air (e.g., air outside the enclosure 100) to pass into the heat exchanger 114, and the port 128 may be considered an exhaust port to allow air to exit the heat exchanger 114. Alternatively, the port 128 may be considered an intake port, and the port 126 may be considered an exhaust port if air enters through the port 128 and exits through the port 126.

In the particular example of FIG. 1, the fan 118 is positioned adjacent the intake port 126 and the fan 116 is positioned adjacent the exhaust port 128. In other embodiments, and as further explained below, one or both fans 116, 118 (and/or additional fans) may be placed in another suitable location along the airflow path 122, the fans may be placed in the other airflow path 120, etc.

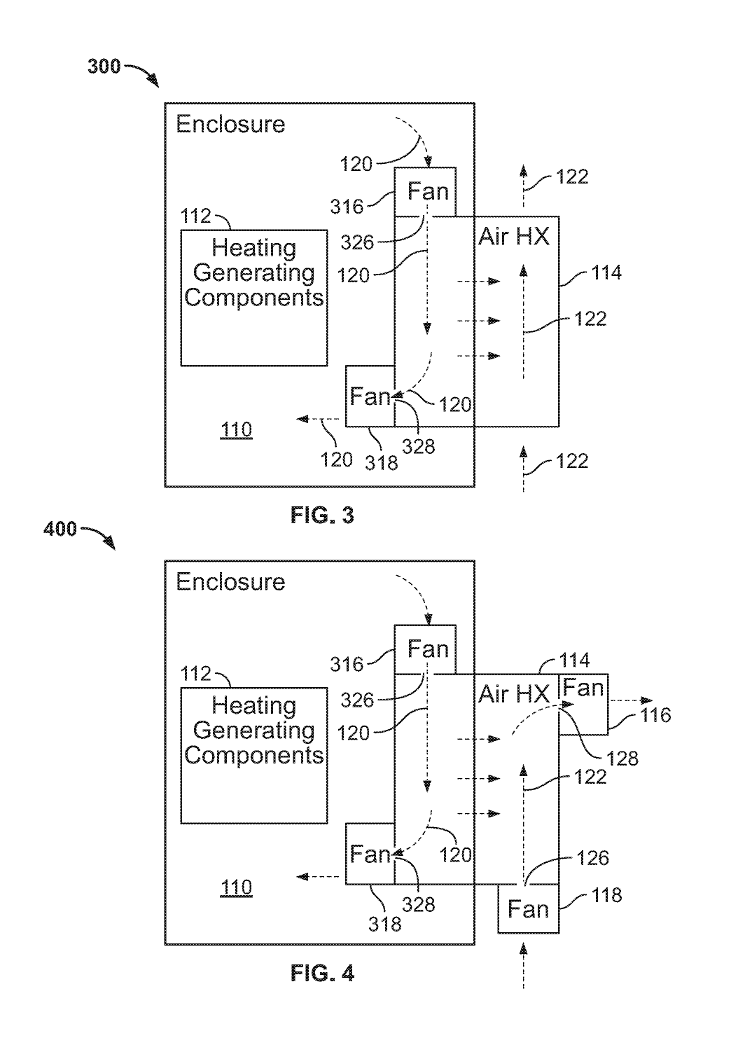

For example, FIG. 3 illustrates a telecommunications equipment enclosure 300 substantially similar to the telecommunications equipment enclosure 100 of FIG. 1, but having fans in the airflow path 120. Specifically, the enclosure 300 includes the chamber 110 of FIG. 1 for housing the heat generating components 112, the air heat exchanger 114 of FIG. 1 defining the airflow paths 120, 122, and two fans 316, 318.

In the particular example of FIG. 3, the two fans 316, 318 are positioned in a series airflow arrangement in the airflow path 120 for moving air through the airflow path 120 and removing heat from the chamber 110. In other words, the fan 316 pulls air internal to the chamber 110 into the heat exchanger 114 and pushes air towards the fan 318, and the fan 318 pulls air out of the heat exchanger 114 and pushes it back into the chamber 110 to create the airflow path 120, as shown in FIG. 3.

The heat exchanger 114 and the fans 316, 318 of FIG. 3 function substantially similar to the heat exchanger 114 and the fans 116, 118 of FIG. 1. For example, the series arranged fans 316, 318 of FIG. 3 move air that is heated by the heat generating component 112 and/or other heat generating components through the air heat exchanger 114 via the airflow path 120 (as explained above). The heat is transferred through the heat exchanger plates (e.g., a portion of the enclosure's wall, internal heat exchanger fins, etc.), and to air in the airflow path 122 flowing through the heat exchanger 114 and external to the chamber 110. As a result, heat is removed from the chamber 110 (and therefore the enclosure 300).

Additionally, the heat exchanger 114 of FIG. 3 includes two ports 326, 328 for allowing ambient air to move into and/or out of the heat exchanger 114, as explained above. In the particular embodiment of FIG. 3, the port 326 is an intake port to allow air to pass into the heat exchanger 114, and the port 328 is an exhaust port to allow air to exit the heat exchanger 114. In the particular example of FIG. 3, the fan 316 is positioned adjacent the intake port 326 and the fan 318 is positioned adjacent the exhaust port 328.

In other embodiments, the enclosures disclosed herein may include two sets of fans. For example, FIG. 4 illustrates a telecommunications equipment enclosure 400 substantially similar to the enclosure 100 of FIG. 1 and the enclosure 300 of FIG. 3, but including two sets of fans. Specifically, the enclosure 400 includes the chamber 110, the heat generating components 112, the air heat exchanger 114, the airflow paths 120, 122, and the fans 116, 118 of FIG. 1, and the fans 316, 318 of FIG. 3.

The air heat exchanger 114 and fans 116, 118, 316, 318 of FIG. 4 function similar to the air heat exchanger 114 and fans 116, 118, 316, 318 of FIGS. 1 and 3 explained above. For example, and as shown in FIG. 4, the fans 116, 118 are positioned in a series airflow arrangement in the airflow path 122 external to the chamber 110, and the fans 316, 318 are positioned in a series airflow arrangement in the airflow path 120 internal to the chamber 110. Additionally, and as explained above, the fan 118 is positioned adjacent the intake port 126, the fan 116 is positioned adjacent the exhaust port 128, the fan 316 is positioned adjacent the intake port 326, and the fan 318 is positioned adjacent the exhaust port 328.

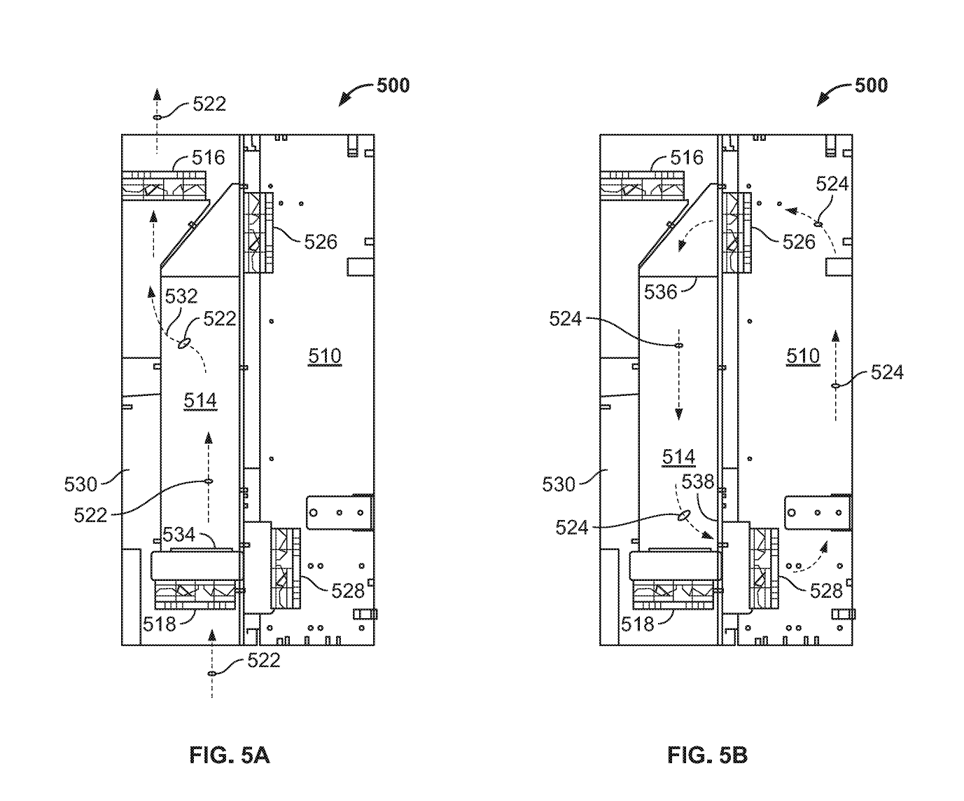

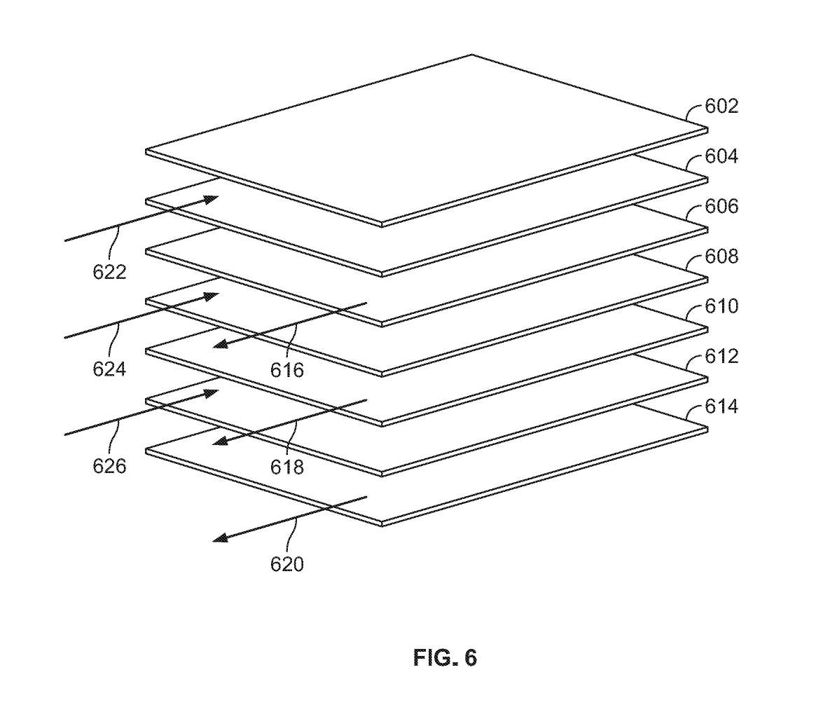

In some embodiments, any of the air heat exchanger disclosed herein may be positioned on and/or a portion of an enclosure's door. For example, FIGS. 5A and 5B each illustrate a telecommunications equipment enclosure 500 substantially similar to the enclosure 400 of FIG. 4, but where an air heat exchanger is positioned on the enclosure's door. Specifically, the enclosure 500 includes various walls defining a chamber 510 housing one or more heat generating components (not shown), a door 530 coupled (e.g., pivotably coupled) to at least one of the walls, an air heat exchanger 514, and four fans 516, 518, 526, 528. As shown, the air heat exchanger 514 is positioned on the door 530. This heat exchanger arrangement may assist in sealing the chamber 510 (if desired), as further explained below.

The air heat exchanger 514 of FIG. 5 may be substantially similar to the air heat exchanger 114 of FIG. 1. For example, the air heat exchanger 514 defines an airflow path 522 through the air heat exchanger 514 and external to the chamber 510 (see FIG. 5A), and another airflow path 524 through the air heat exchanger 514 and internal to the chamber 510 (see FIG. 5B). Similar to the airflow paths 120, 122 of FIG. 1, the airflow paths 522, 524 of FIG. 5 are isolated (e.g., segregated) from each other.

Additionally, the fans 516, 518, 526, 528 of FIG. 5 may be substantially similar to the fans 116, 118, 316, 318 of FIG. 4. For example, two of the fans 516, 518 are positioned in a series airflow arrangement in the airflow path 522 and move air through the airflow path 522. The other two fans 526, 528 are positioned in a series airflow arrangement in the airflow path 524 and move air through the airflow path 524. As shown in FIGS. 5A and 5B, the fan 516 is positioned adjacent the enclosure's exhaust port 532 allowing air to exit the heat exchanger 514 (and the enclosure 500), and the fan 518 is positioned adjacent the enclosure's intake port 534 allowing air to pass into the heat exchanger 514. The fan 526 is positioned adjacent the enclosure's intake port 536 allowing air to pass into the heat exchanger 514, and the fan 528 is positioned adjacent the enclosure's exhaust port 538 allowing air to exit the heat exchanger 514.

FIG. 6 illustrates a set of thermally conductive plates (e.g., fins) suitable for any one of the heat exchangers disclosed herein. The set includes plates 602, 604, 606, 608, 610, 612, 614 spaced apart from each. The distance between adjacent plates may depend on, for example, the size of the heat exchanger core, the number of plates in the heat exchanger core, etc.

As shown, the thermally conductive plates of FIG. 6 define six different airflow paths (indicated by arrows 616, 618, 620, 622, 624, 626) through a heat exchanger. For example, the plates 604, 606 define an airflow path 616, the plates 608, 610 define an airflow path 618, the plates 612, 614 define an airflow path 620, the plates 602, 604 define an airflow path 622, the plates 606, 608 define an airflow path 624, and the plates 610, 612 define an airflow path 626.

Some of the airflow paths may represent air moving through the air heat exchanger and internal to the enclosure's chamber, and other airflow paths may represent air moving through the air heat exchanger and external to the enclosure's chamber. For example, the airflow paths 616, 618, 620 may represent internal air airflow paths, and the airflow paths 622, 624, 626 may represent external air airflow paths, as explained above.

In the particular embodiment of FIG. 6, air in the airflow paths 616, 618, 620 is moving in an opposite direction as air in the airflow paths 622, 624, 626. Alternatively, air in the airflow paths 616, 618, 620 may move in the same direction, a perpendicular direction, etc. as air in the airflow paths 622, 624, 626.

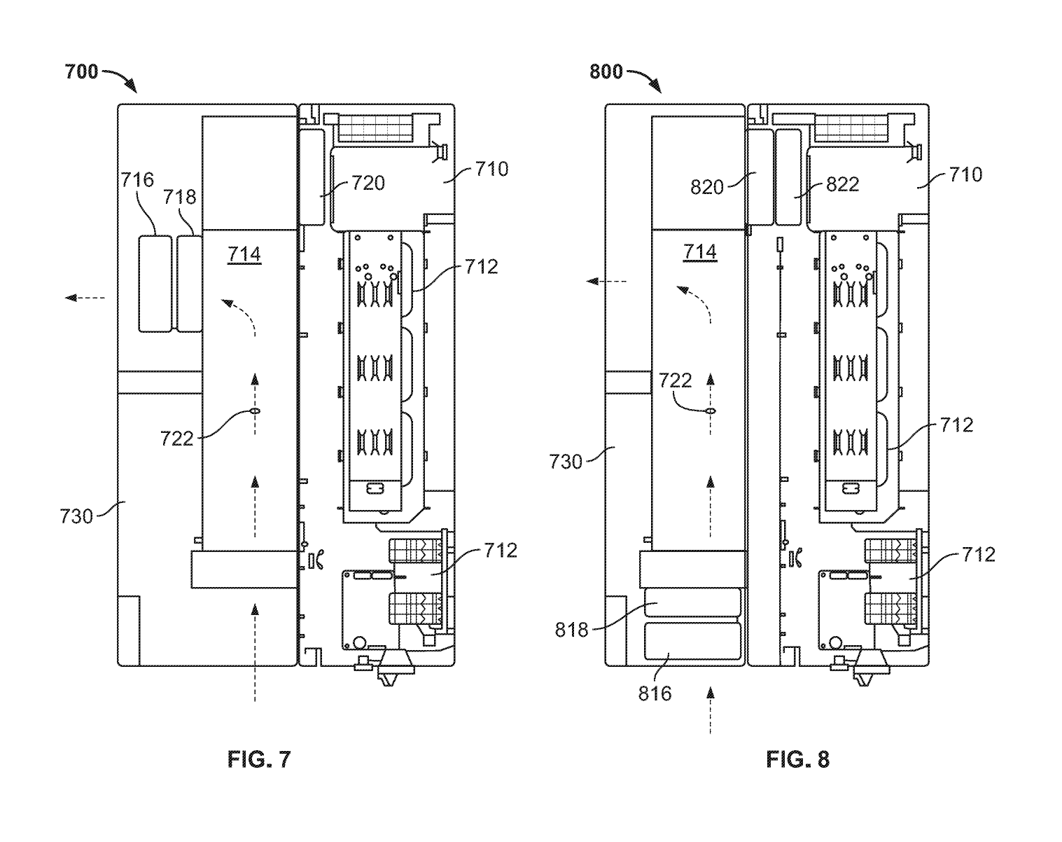

In some embodiments, the fans disclosed herein may be positioned adjacent to each other and in a series airflow arrangement (as explained above). For example, FIGS. 7 and 8 illustrate enclosures 700, 800 substantially similar to the enclosure 500 of FIGS. 5A and 5B, but including fans adjacent each other. Specifically, the enclosures 700, 800 each include various walls defining a chamber 710 housing one or more heat generating components 712, a door 730 coupled to at least one of the walls, an air heat exchanger 714 positioned on the door 730, and various fans.

The air heat exchanger 714 may be substantially similar to the air heat exchangers 114, 514 of FIGS. 1-5. For example, the heat exchanger 714 may define multiple airflow paths including an airflow path 722 through the heat exchanger 714 and external to the chamber 710. Although not shown, the heat exchanger 714 may define one or more additional airflow paths including an airflow path through the heat exchanger 714 and internal to the chamber 710, as explained herein.

As shown in FIG. 7, the enclosure 700 includes three fans 716, 718, 720. In the particular example of FIG. 7, the fan 720 is positioned on an internal side of the heat exchanger 714. Additionally, the fans 716, 718 are positioned adjacent each other and in a series airflow arrangement in the external airflow path 722 for moving air through the path 722 and removing heat from the chamber 710, as explained above. In the particular example of FIG. 7, the fans 716, 718 are positioned adjacent an exhaust port of the heat exchanger 714. In other examples, the fans 716, 718 may be positioned adjacent an intake port (and along the airflow path 722) of the heat exchanger 714, in another airflow path, etc.

As shown in FIG. 8, the enclosure 800 includes four fans 816, 818, 820, 822. Like the fans 716, 718 of FIG. 7, the fans 816, 818 are positioned adjacent each other and in a series airflow arrangement in the external airflow path 722 for moving air through the path 722 and removing heat from the chamber 710. However, in the particular example of FIG. 8, the fans 816, 818 are positioned adjacent an intake port of the heat exchanger 714. Additionally, the fans 820, 822 are positioned adjacent each other and in a series airflow arrangement in another airflow path, as explained herein. As shown, the fans 820, 822 are positioned on an internal side of the heat exchanger 714.

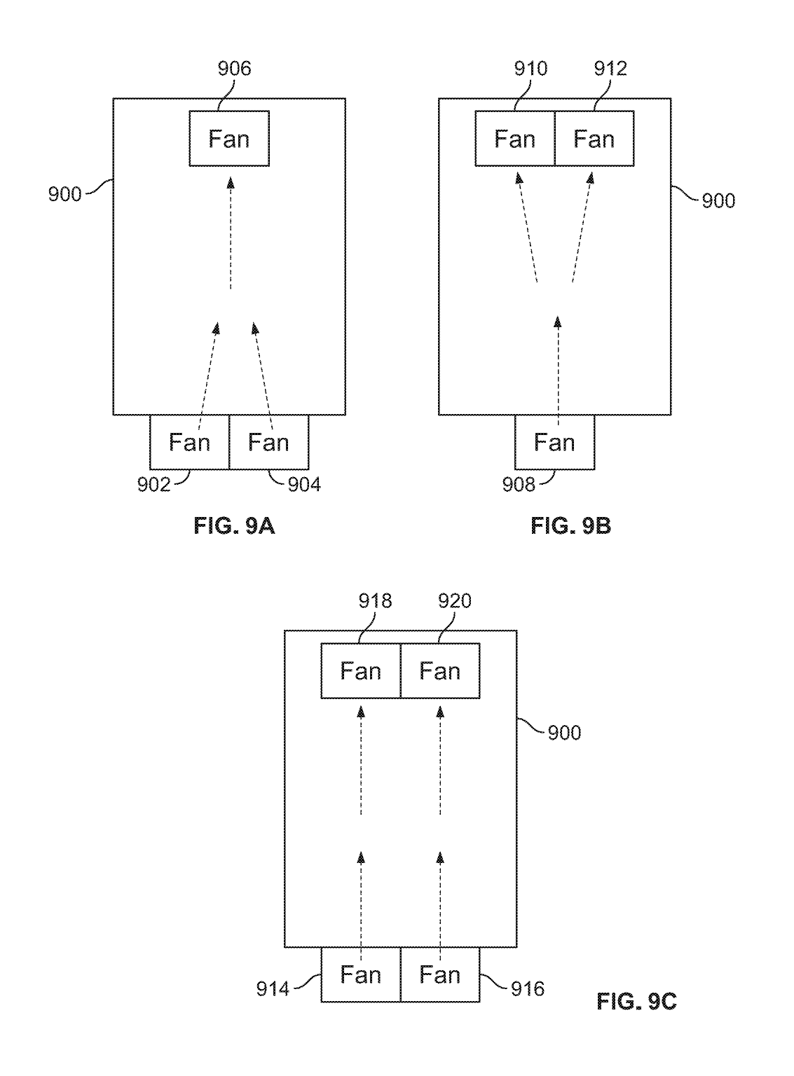

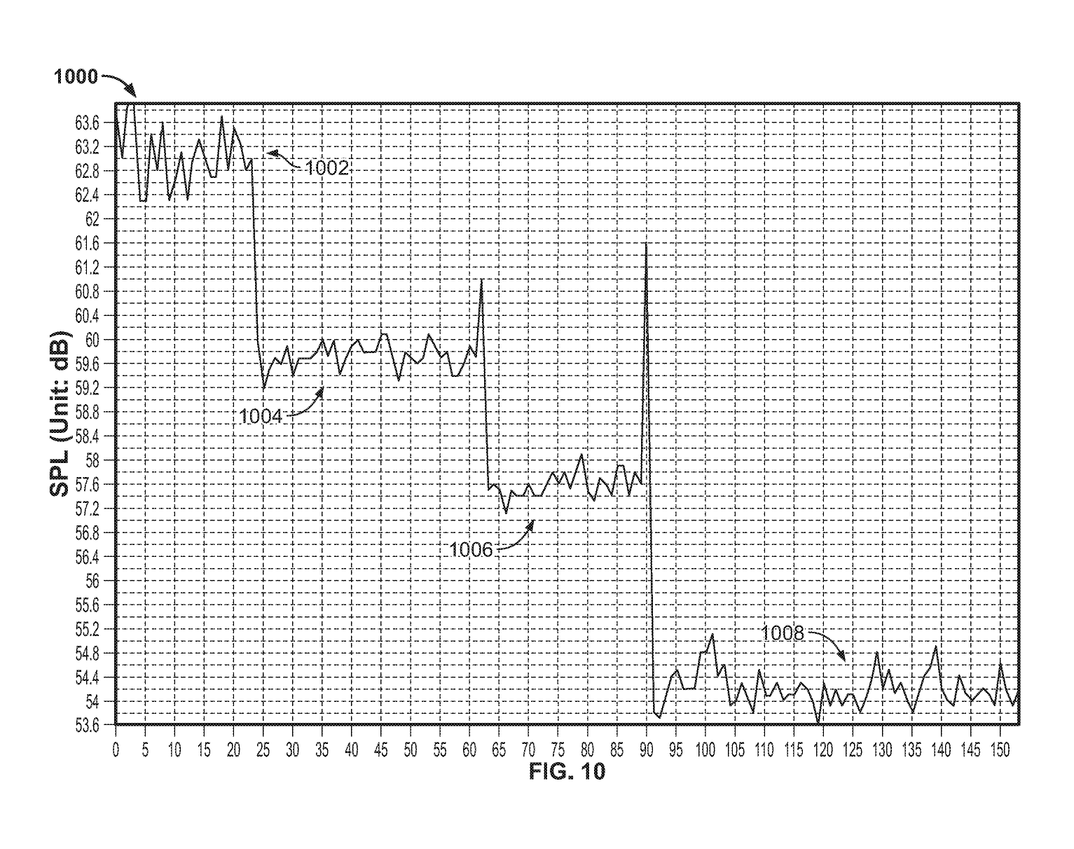

Although the enclosures shown in FIGS. 1-5 and 7 illustrate embodiments having a series arrangement formed of two fans, it should be apparent to those skilled in the art that additional fans may be added if desired. For example, FIGS. 9A, 9B and 9C each illustrate a portion of an enclosure having a heat exchanger 900 and various fans employable in an enclosure including the enclosures disclosed herein.

In the particular example of FIG. 9A, the enclosure includes three fans 902, 904, 906. As shown, the fans 902, 904 are positioned in a parallel airflow arrangement (e.g. a side-by-side fan arrangement) to create two airflow paths. In this example, the airflow paths of the two parallel arranged fans 902, 904 converge and pass through the fan 906 in a push-pull arrangement. Thus, the fans 902, 904 (in combination) are in a series airflow arrangement with the fan 906.

In other embodiments, the push-pull arrangement may be reversed. For example, and as shown in FIG. 9B, the enclosure includes three fans 908, 910, 912. The fans 910, 912 are positioned in a parallel airflow arrangement (e.g. a side-by-side fan arrangement). The combination of the fans 910, 912 is then positioned in a series airflow arrangement with the fan 908. As such, the fan 908 may create an airflow path that diverges into two airflow paths for passing through the fans 910, 912.

As shown in FIG. 9C, the enclosure includes four fans 914, 916, 918, 920 in which two of the fans are positioned in a series airflow arrangement and the other two of the fans are positioned in another series airflow arrangement. For example, the fans 914, 918 are positioned in a series airflow arrangement (e.g., a push-pull arrangement), and the fans 916, 920 are positioned in another series airflow arrangement.

Although the enclosures disclosed herein include fans at specific locations (e.g., adjacent to an intake port, an exhaust port, etc.), it should be apparent to those skilled in the art that one or more fans (including those disclosed herein) can be placed in any suitable position along an airflow path. For example, one fan may be adjacent the intake port and another fan may be between the intake port and the exhaust port. In some embodiments, one fan may be adjacent the intake port, another fan may be adjacent the exhaust port, and another fan may be between the intake port and the exhaust port. In other embodiments, two fans may be positioned between the intake port and the exhaust port.

As explained herein, by employing an air heat exchanger having an airflow path and series arranged fans for moving air through the airflow path, the fans may be operated at lower speeds as compared to fans in conventional systems. The lower speeds may reduce the amount of fan noise compared to conventional systems, and still provide enough airflow through the heat exchanger's fluid paths for sufficient heat transfer.

For example, testing has shown that fans positioned in a series airflow arrangement can have a noise reduction of about 3.5 dB, which equates to a sound power reduction of over 50%, as shown in Table 1 below. Specifically, testing was conducted using one or more 120 mm fans. As shown in Table 1, a single fan operated at 2590 RPM (see test 2) generates a noise level of 54.9 dB. However, this fan does not meet a defined heat removal requirement in a heat exchanger. As such, the speed of the fan was increased to 3010 RPM (see test 3) to meet the defined heat removal requirement. At this fan speed, the noise was measured at 58.2 dB.

TABLE 1

| | | | Fan | |
|---|---|---|---|---|
| Test | Description | Duty Cycle | RPM | Noise (dB) |
| Test 1 | Baseline | 0 | 0 | 36.6 |
| Test 2 | Single Fan | 29 | 2590 | 54.9 |
| Test 3 | Single Fan | 33 | 3010 | 58.2 |
| Test 4 | Two Fans, series, stacked | 32 | 2080 | 55.4 |
| Test 5 | Two Fans, series, stacked | 39 | 2360 | 57.2 |
| Test 6 | Two Fans, series, | 29 | 2460 | 54.7 |
| | intake/exhaust | | | |
| Test 7 | Two Fans, series, | 35 | 2630 | 56.3 |
| | intake/exhaust | | | |

As shown in tests 4-7 in Table 1, if two fans are positioned in a series airflow arrangement as explained herein, the fans speed may be reduced which causes the generated noise to fall. For example, test 6 of Table 1 includes two fans positioned in a series airflow arrangement. One fan is positioned adjacent the heat exchanger's intake port and the other fan is positioned adjacent the heat exchanger's exhaust port. To meet the defined heat removal requirement, the series arranged fans may be operated at 2460 RPM which generates a noise level of 54.7 dB. This equates to a 3.5 dB noise reduction (and over 50% in sound power reduction) when compared to the single fan operated at 3010 RPM (test 3). Additionally, testing has shown that the fans may be operated at speeds as low as 2300 RPM and still meet the defined heat removal requirement. For example, when operated at 2300 RPM, the noise generated may be about 54 dB. This equates to about a 4.2 dB noise reduction when compared to the single fan operated at 3010 RPM (test 3).

Further testing indicates that fan speed and noise may be reduced if more than two fans are employed (e.g., the fan configurations shown in FIGS. 9A and 9C explained above). For example, FIG. 10 illustrates a graph 1000 plotting the noise produced over time for a conventional fan configuration having two fans in a parallel arrangement (represented by regions 1002, 1006) and the fan configuration shown in FIG. 9A (represented by regions 1004, 1008). The regions 1002, 1004 represent testing performed with one brand of fans (hereinafter “brand X”) and the regions 1006, 1008 represent testing performed with another brand of fans (hereinafter “brand Y”).

For similar heat removal, the fans represented in region 1002 (i.e., the conventional fan configuration using brand X fans) were operated at 3080 RPM, and the fans represented by region 1004 (i.e., the fan configuration of FIG. 9A using brand X fans) were operated at 2546 RPM. As shown, the average noise produced by the fans represented in region 1002 was about 63 dB, and the average noise produced by the fans represented in region 1004 was about 59.6 dB. Thus, the noise generated by the series arranged fans represented in region 1004 is about 3.4 dB less than the noise generated by the parallel arranged fans represented in region 1002 while removing a similar amount of heat.

Likewise, for similar heat removal, the fans represented in region 1006 (i.e., the conventional fan configuration using brand Y fans) were operated at 3420 RPM, and the fans represented by region 1008 (i.e., the fan configuration of FIG. 9A using brand Y fans) were operated at 2580 RPM. As shown, the average noise produced by the fans represented in region 1006 was about 57.6 dB, and the average noise produced by the fans represented in region 1008 was about 54.1 dB. Thus, the noise generated by the series arranged fans represented in region 1008 is about 3.5 dB less than the noise generated by the parallel arranged fans represented in region 1006 while removing a similar amount of heat.

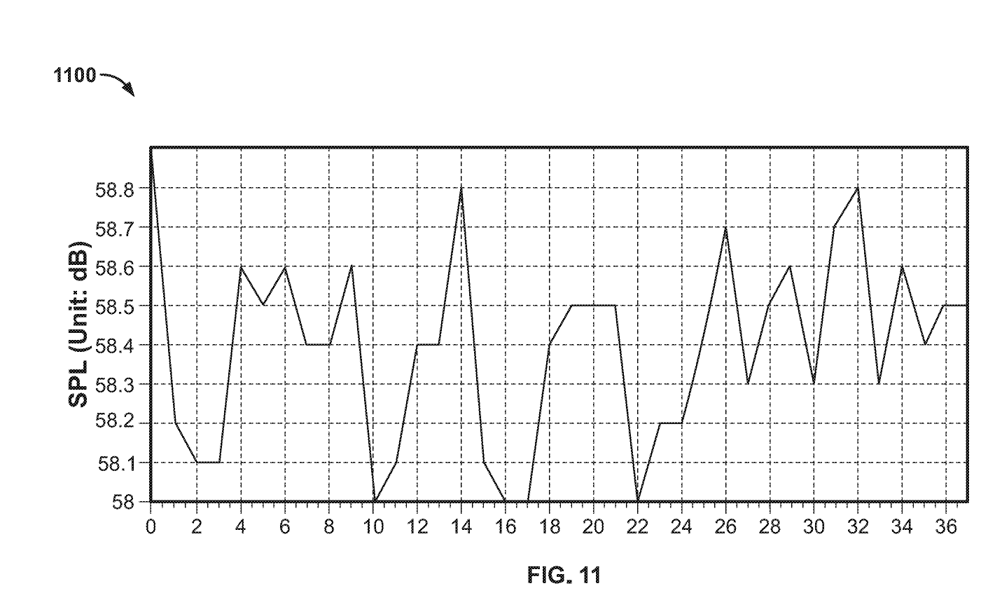

FIG. 11 illustrates a graph 1100 plotting the noise produced over time for the fan configuration shown in FIG. 9C. The testing data shown in the graph 1100 was generated using the brand X fans, as referenced above. As shown, the average noise produced was about 58.4 dB.

Additionally, testing for different configurations having more than two fans is shown in Table 2 below. As shown, fan speed and noise may be reduced when multiple fans in a series airflow arrangement are employed as compared to conventional parallel airflow arrangements. For example, Table 2 shows data for three fans positioned in a parallel airflow arrangement (see Tests 1, 3, 4, 6), two fans positioned in a parallel airflow arrangement (see Tests 2, 5), four fans positioned in a series airflow arrangement (see Test 7), and five fans positioned in a series airflow arrangement (see Test 8). As shown in test 7 (e.g., the FIG. 9C fan configuration), the fans were operated at 2350 RPM to achieve a thermal conductivity (heat removal) of 35.5 W/K while generating a noise level of about 54.5 dB. Additionally, in test 8, the fans were operated at 2150 RPM to achieve a thermal conductivity (heat removal) of 35.5 W/K while generating a noise level of about 54.3 dB. As shown in Table 2, when removing about the same about of heat, the parallel arranged fans (Tests 1-5) were forced to operate at higher speeds. As a result, the fans generated a higher noise level than the series arranged fans (tests 7, 8). In other cases, the speed of the parallel arranged fans may be reduced (e.g., to 2400 RPM in Test 6). However, the thermal conductivity (29.5 W/K) may decrease to unsatisfactory level.

TABLE 2

| | | Heat | | |
|---|---|---|---|---|
| | | Removal | Fan | Noise |
| Test | Description | (W/K) | (RPM) | (dB) |
| Test 1 | Three fans, parallel | 35.5 | 2750 | 59.6 |
| | (conventional | | | |
| | configuration) | | | |
| Test 2 | Two fans, parallel | 35.5 | 3050 | 60.1 |
| | (conventional | | | |
| | configuration) | | | |
| Test 3 | Three fans, parallel | 32 | 2400 | 56.7 |
| | (conventional | | | |
| | configuration) | | | |
| Test 4 | Three fans, parallel | 35.5 | 2750 | 59.6 |
| | (conventional | | | |
| | configuration) | | | |
| Test 5 | Two fans, parallel | 35.5 | 3050 | 60.1 |
| | (conventional | | | |
| | configuration) | | | |
| Test 6 | Three fans, parallel | 29.5 | 2400 | 56.7 |
| | (conventional | | | |
| | configuration) | | | |
| Test 7 | Four Fans, series | 35.5 | 2350 | 54.5 |
| | (FIG. 9C | | | |
| | configuration) | | | |
| Test 8 | Five Fans, series | 35.5 | 2150 | 54.3 |
| | (3 by 2 | | | |
| | configuration) | | | |

Further, lower required fan speed allows users to employ smaller fans. As such, the enclosures disclosed herein may include smaller fans as compared to conventional systems when series arranged fans are employed. For example, the fans disclosed herein may be fans having any suitable edge-to-edge distance based on heat transfer requirements, static pressure, heat exchanger design (e.g., plate configuration, etc.), etc. In some embodiments, the fans may be 120 mm fans, larger or smaller than 120 mm fans, etc.

In some examples, the heat exchangers may include (or at least a part of) the fans. In such examples, the size of the heat exchangers may be reduced (e.g., due to the smaller fans) as compared to conventional heat exchangers, while maintaining sufficient heat transfer characteristics. This allows a variety of different sized enclosures, including small enclosures having high heat densities, to employ the heat exchangers.

The telecommunications equipment enclosures disclosed herein may be used in various applications. For example, the enclosures may be deployed indoors and/or outdoors. As such, the enclosures may be installed and operational in any various locations including, for example, on poles, walls (e.g., interior walls, exterior walls, etc. of a building, etc.), pads, etc. Additionally, the telecommunications equipment enclosures may include various components such as telecommunications equipment, sound dampening components (e.g., if further reduction in noise is desired), etc. Some or all of the telecommunications equipment may be housed in the chambers. The telecommunications equipment may include components (e.g., electronic components) vulnerable to heat and the heat generating components. Specifically, the telecommunications equipment may include, for example, rectifiers, converters, inverters, batteries, switching devices, controllers, radio components, cellular components, splicing equipment, etc.

The chambers disclosed herein may include any suitable chamber for housing one or more heat generating components. For example, the chambers may include sealed chambers (e.g., environmentally sealed chambers). In such examples, the chambers may include appropriate gaskets, seals, potting, etc. to ensure moisture, dirt, air, dust, etc. is prohibited from entering.

The heat exchangers disclosed herein may form a portion of one or more of the enclosure's walls, may be coupled to one or more of the enclosure's walls, etc. In some embodiments, the heat exchangers may be a portion of the enclosure's door, as explained above. Additionally and/or alternatively, at least a portion (and sometimes the entirety) of the heat exchangers are positioned inside the enclosure and/or the chamber. In other examples, the heat exchangers need not enter into the enclosure and/or the chamber.

Additionally, the heat exchangers may be any suitable size including, for example, about two (2) feet by about one and a half (1%) feet by about one and a half (1%) feet. In other embodiments, the heat exchangers may be smaller or larger depending on enclosure parameters, fan characteristics, etc.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A telecommunications equipment enclosure, comprising:
a plurality of walls defining a chamber for housing a heat generating component;
an air heat exchanger defining a first airflow path through the air heat exchanger and internal to the chamber, and a second airflow path through the air heat exchanger and external to the chamber;
at least two fans positioned in a series airflow arrangement in the first airflow path for moving air through the first airflow path and removing heat from the chamber; and
at least two fans positioned in a series airflow arrangement in the second airflow path for moving air through the second airflow path and removing heat from the chamber.

2. The telecommunications equipment enclosure of claim 1 wherein the air heat exchanger includes an intake port to allow air to pass into the air heat exchanger and an exhaust port to allow air to exit the air heat exchanger, wherein the intake port and the exhaust port are each in fluid communication with the first airflow path or the second airflow path, wherein one of the at least two fans in the first airflow path or one of the at least two fans in the second airflow path is positioned adjacent the intake port, and wherein another one of the at least two fans in the first airflow path or another one of the at least two fans in the second airflow path is positioned adjacent the exhaust port.

3. The telecommunications equipment enclosure of claim 1 wherein the air heat exchanger includes an intake port to allow air to pass into the air heat exchanger and an exhaust port to allow air to exit the air heat exchanger, wherein the intake port and the exhaust port are each in fluid communication with the first airflow path or the second airflow path, and wherein the at least two fans in the first airflow path or the at least two fans in the second airflow path are positioned adjacent the intake port.

4. The telecommunications equipment enclosure of claim 1 wherein the air heat exchanger includes an intake port to allow air to pass into the air heat exchanger and an exhaust port to allow air to exit the air heat exchanger, wherein the intake port and the exhaust port are each in fluid communication with the first airflow path or the second airflow path, and wherein the at least two fans in the first airflow path or the at least two fans in the second airflow path are positioned adjacent the exhaust port.

5. The telecommunications equipment enclosure of claim 1 further comprising another fan positioned in a parallel airflow arrangement with one of the at least two fans in the first airflow path or one of the at least two fans in the second airflow path.

6. The telecommunications equipment enclosure of claim 1 wherein the chamber is an environmental sealed chamber.

7. The telecommunications equipment enclosure of claim 1 further comprising a door, wherein the air heat exchanger is positioned on the door.

8. The telecommunications equipment enclosure of claim 1 wherein the at least two fans in the first airflow path are the only fans in the first airflow path, and wherein the two fans are each configured to operate at 2300 revolutions per minute and at a noise level of 54 dB.

9. A telecommunications equipment enclosure including a plurality of walls defining a chamber for housing a heat generating component, an air heat exchanger defining a first airflow path through the air heat exchanger and internal to the chamber and a second airflow path through the air heat exchanger and external to the chamber, and a first fan positioned in the first airflow path or the second airflow path for generating a required airflow at a particular speed and a particular noise level, the improvement comprising:
a second fan positioned in a series airflow arrangement with the first fan for generating the required airflow, the series airflow arrangement allowing each of the first fan and the second fan to operate at a lower speed than said particular speed and at a combined noise level lower than said particular noise level.

10. The telecommunications equipment enclosure of claim 9 wherein said lower speed is 2300 revolutions per minute and said combined noise level is 54 dB.

11. The telecommunications equipment enclosure of claim 9 wherein said lower speed is at least 500 revolutions per minute less than said particular speed.

12. The telecommunications equipment enclosure of any preceding claim 9 wherein said combined noise level is at least 3.5 decibel less than said particular noise level.

13. A telecommunications equipment enclosure, comprising:
a plurality of walls defining a chamber for housing a heat generating component;
an air heat exchanger defining a first airflow path through the air heat exchanger and internal to the chamber, and a second airflow path through the air heat exchanger and external to the chamber; and
at least two fans positioned in a series airflow arrangement in the first airflow path or the second airflow path, the at least two fans configured to move air through the first airflow path or the second airflow path to remove heat from the chamber.

14. The telecommunications equipment enclosure of claim 13 further comprising a door, wherein the air heat exchanger is positioned on the door.

15. The telecommunications equipment enclosure of claim 13 wherein the air heat exchanger includes an intake port to allow air to pass into the air heat exchanger and an exhaust port to allow air to exit the air heat exchanger, wherein the intake port and the exhaust port are each in fluid communication with the first airflow path or the second airflow path, wherein one of the at least two fans is positioned adjacent the intake port, and wherein another one of the at least two fans is positioned adjacent the exhaust port.

16. The telecommunications equipment enclosure of claim 15 further comprising another fan positioned in a parallel airflow arrangement with one of the at least two fans positioned in the first airflow path or the second airflow path.

17. The telecommunications equipment enclosure of claim 13 wherein the air heat exchanger includes an intake port to allow air to pass into the air heat exchanger and an exhaust port to allow air to exit the air heat exchanger, wherein the intake port and the exhaust port are each in fluid communication with the first airflow path or the second airflow path, and wherein the at least two fans are positioned adjacent the intake port.

18. The telecommunications equipment enclosure of claim 13 wherein the air heat exchanger includes an intake port to allow air to pass into the air heat exchanger and an exhaust port to allow air to exit the air heat exchanger, wherein the intake port and the exhaust port are each in fluid communication with the first airflow path or the second airflow path, and wherein the at least two fans are positioned adjacent the exhaust port.

19. The telecommunications equipment enclosure of claim 13 wherein the chamber is an environmental sealed chamber.

20. The telecommunications equipment enclosure of claim 13 wherein the at least two fans includes two fans each configured to operate at 2300 revolutions per minute and at a noise level of 54 dB.
